(19) United States
(12) Patent Application Publication
(10) Pub. No.: US 2004/0261833 A1
(43) Pub. Date: Dec. 30, 2004

(54) Thermoelectric conversion material, thermoelectric conversion element using the material, and electric power generation method and cooling method using the element

(76) Inventors: Yasuhiro Ono, Miyagi (JP); Shingo Inayama, Miyagi (JP); Yuzuru Miyazaki, Miyagi (JP); Tsuyoshi Kajitani, Miyagi (JP); Satoshi Yotsuhashi, Hyogo (JP); Hideaki Adachi, Osaka (JP)

Correspondence Address: MCDERMOTT, WILL & EMERY, 600 13th Street, N.W., Washington, DC, 20005-3096, US

(21) Appl. No.: 10/828,553

(22) Filed: Apr. 21, 2004

(30) Foreign Application Priority Data
Apr. 22, 2003 (JP) 2003-116840

(51) Int. Cl. H01L 35/28; H01L 35/12

(52) U.S. Cl. 136/236.1

(57) ABSTRACT

The present invention provides a thermoelectric conversion material including a half-Heusler alloy represented by the formula QR(L₁₋ₚZₚ), where Q is at least one element selected from group 5 elements, R is at least one element selected from cobalt, rhodium and iridium, L is at least one element selected from tin and germanium, Z is at least one element selected from indium and antimony, p is a numerical value that is equal to or greater than 0 and less than 0.5. A preferable example of the half-Heusler alloy is NbCo(Sn₁₋ₚSbₚ). The thermoelectric conversion material according to the present invention is n-type, and therefore, it is desired that the material is combined with a p-type thermoelectric conversion material to make a thermoelectric conversion element.

### BACKGROUND OF THE INVENTION

1. Field of the Invention

The present invention relates to a thermoelectric conversion material that converts thermal energy and electric energy from one into the other by a thermoelectric effect, and a thermoelectric conversion element using the material. The present invention also relates to methods of converting energy using the element, such as electric power generation methods and cooling methods.

2. Description of the Related Art

Thermoelectric power generation is a technology for directly converting thermal energy into electric energy with the use of the Seebeck effect, a phenomenon in which a temperature difference given to opposing ends of a substance causes a thermal electromotive force in proportion to the temperature difference. The electric energy can be taken out as electric power by connecting a load thereto and forming a closed circuit. This technology has been in practical use as power supplies for remote areas, power supplies for aerospace use, power supplies for military use, and the like.

Thermoelectric cooling is a technology for causing heat absorption with the use of the Peltier effect, a phenomenon in which passage of an electric current through a circuit made of different substances connected each other causes heat absorption in one junction and heat generation in the other junction. This technology has been in practical use as local cooling devices such as for cooling electronic devices in a space station, wine coolers, and the like.

What is useful for widening the uses of thermoelectric conversion materials is a material that demonstrates a high thermoelectric conversion characteristic (thermoelectric performance) in the vicinity of room temperature and is suitable for cooling, and a material that demonstrates good thermoelectric performance in a wide temperature range ranging from room temperatures to high temperatures and is suitable for power generation. Based on this, various materials typified by semiconductors have been studied as thermoelectric conversion materials.

Generally, thermoelectric performance is evaluated by a figure of merit Z, or a figure of merit ZT that is made dimensionless by multiplying Z by an absolute temperature T. The figure of merit ZT is represented as ZT=S²ρκ, where S is Seebeck coefficient, ρ is electric resistivity, and κ is thermal conductivity. To date, the figure of merit ZT has not exceed, more or less, the barrier of 1. This is due to the fact that S, ρ, and κ are basically functions of carrier density and therefore difficult to vary independently of one another. Another index of thermoelectric performance is a power factor P. With S and ρ, the factor P is represented as P=S²/ρ.

Representative examples of thermoelectric conversion materials for industrial use include Bi₂Te₃-based materials and PbTe-based materials. These materials, however, are undesirable in terms of their adverse effects to environment. In particular, since the above-noted materials are poor in heat resistance and oxidation resistance, the materials create the problem of environmental pollution associated with vaporization and oxidation decomposition at high temperatures. In addition, the above-noted materials require large cost in various processes such as purchasing the source material, fabricating, and recycling. Moreover, the thermoelectric performance of the materials is greatly dependent on temperature, and the temperature range in which good performance is obtained is very narrow.

Conventionally, researches on Heusler alloys and half-Heusler alloys have centered around their magnetic properties and their electrical conduction. FIG. 1 shows the crystal structure of half-Heusler alloy, which is represented by the formula QRL. In this crystal structure, lattices in which atoms are present in R positions in the space constituted by Q positions and L positions and lattices in which these positions are holes are arrayed alternately. In contrast, a group of substances represented by the formula QR₂L, in which atoms are present in all the R positions, are referred to as Heusler alloys. Half-Heusler alloys have a lattice constant of about 4.2 Å (0.42 nm) on average, and this is larger than that of Heusler alloys, which is about 3.0 Å (0.30 nm). As a consequence, half-Heusler alloys tend to be in other states than metals, such as semiconductors and semimetals.

JP 2001-189495 A discloses a guideline on the combinations of atoms for providing a half-Heusler alloy with good thermoelectric performance. According to this guideline, neutral atom-forming atoms, which eliminate an insufficient electron-occupying state in s orbitals, p orbitals, and d orbitals and form neutral atoms, cation-forming atoms, which eliminate an insufficient electron-occupying state in the above-noted orbits and form cations, and anion-forming atoms, which eliminate an insufficient electron-occupying state in the above-noted orbits and form anions are combined so as to maintain equilibrium in the electric charge based on the cation-forming atoms and the anion-forming atoms. JP 2001-189495 A discloses PtGdBi as being a half-Heusler alloy that meets the foregoing guideline.

Pt has an electron configuration of [Xe]4f¹⁴5d⁹6s¹. According to JP 2001-189495 A, in PtGdBi, 5d⁹ orbital of Pt receives one electron from Gd and becomes 5d¹⁰ orbital, and 6s¹ orbital of Pt releases one electron to Bi. Thus, the electron configuration Pt becomes [Xe]4f¹⁴5d¹⁰ without changing the number of electrons. That is, while Pt remains neutral, it eliminates insufficient electron-occupying states in s orbitals, p orbitals, and d orbitals. The half-Heusler alloy disclosed in JP 2001-189495 A requires the neutral atom-forming atoms such as Pt and Ni as well as the cation-forming atoms such as Gd and the anion-forming atoms such as Bi.

### SUMMARY OF THE INVENTION

Half-Heusler alloys for use as thermoelectric conversion materials have not yet been studied sufficiently. For this reason, there is a possibility that a study on half-Heusler alloys may result in a thermoelectric conversion material that is suitable for a wider range of uses. It is an object of the present invention to provide a novel thermoelectric conversion material using a half-Heusler alloy.

As a result of intensive research, it has been found that good thermoelectric performance can be obtained by a half-Heusler alloy that does not meet the foregoing conventionally-known guideline. The present invention provides a thermoelectric conversion material that includes a half-Heusler alloy represented by the formula QR(L₁₋ₚZₚ).

In the formula, Q is at least one element selected from group 5 elements (group VA elements in the periodic table according to the old IUPAC system: vanadium, niobium and tantalum), R is at least one element selected from cobalt, rhodium, and iridium, L is at least one element selected from tin and germanium, Z is at least one element selected from indium and antimony, and p is a numerical value that is equal to or greater than 0 and less than 0.5.

The thermoelectric conversion material of the present invention may be used as a thermoelectric conversion element that includes, together with the thermoelectric conversion material, an electrode electrically connected to this material. This element may be configured as, for example, a thermoelectric conversion element including the thermoelectric conversion material of the present invention and a first electrode and a second electrode that are connected to this material. This element may further include a p-type thermoelectric conversion material connected to at least one of the first electrode and the second electrode, and may further include an insulator connected to at least one of the first electrode and the second electrode.

In addition, the present invention also provides a thermoelectric conversion element that includes n-type thermoelectric conversion materials and p-type thermoelectric conversion materials. The n-type thermoelectric conversion materials and the p-type thermoelectric conversion materials are connected alternately and electrically in series, and at least one of, or preferably all of, the n-type thermoelectric conversion materials is the thermoelectric conversion material of the present invention.

In accordance with another aspect, the present invention provides use of the half-Heusler alloy represented by the foregoing formula as a thermoelectric conversion material. In accordance with yet another aspect, the present invention provides use of the half-Heusler alloy represented by the foregoing formula for the manufacture of a thermoelectric conversion element.

In accordance with still another aspect, the present invention provides a method of converting thermal energy and electric energy from one to the other by the thermoelectric effect (the Seebeck effect or the Peltier effect) of a thermoelectric conversion material including a half-Heusler alloy represented by the foregoing formula.

This method of converting can be implemented, for example, as an electric power generating method of using the above-described thermoelectric conversion element that includes the thermoelectric conversion material of the present invention. The method includes supplying heat so that a temperature difference is caused between the first electrode and the second electrode so as to produce a potential difference between the first electrode and the second electrode. The above-described conversion method can be implemented, for example, as a cooling method of using the foregoing thermoelectric conversion element. In the method, a potential difference is caused between the first electrode and the second electrode so as to produce a temperature difference between the first electrode and the second electrode such that either one of the first electrode and the second electrode is made a low temperature part.

A thermoelectric conversion material according to the present invention exhibits good thermoelectric performance over a wide temperature range and shows particularly high thermoelectric performance in a high temperature range. Since the thermoelectric conversion material according to the present invention can be produced from source materials that are relatively inexpensive and readily available, such as niobium, cobalt, and tin, they are suitable for mass production.

### BRIEF DESCRIPTION OF THE DRAWINGS

FIG. 1 illustrates the crystal structure of a half-Heusler alloy;

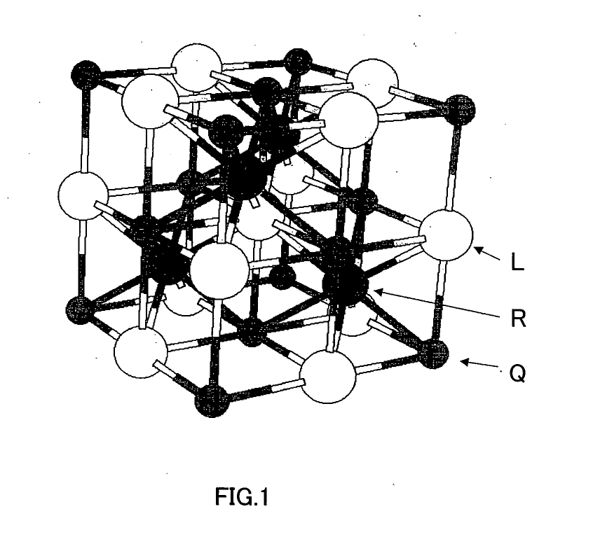

FIG. 2 illustrates the configuration of one example of a thermoelectric conversion element according to the present invention;

FIG. 3 illustrates the configuration of another example of the thermoelectric conversion element according to the present invention;

FIG. 4 illustrates the configuration of yet another example of the thermoelectric conversion element according to the present invention;

FIG. 5 is a cross-sectional view of still another example of the thermoelectric conversion element according to the present invention;

FIG. 6 shows an example of X-ray diffraction chart of NbCoSn;

FIG. 7 shows Seebeck coefficient dependence on temperature, in which FIG. 7A shows the coefficient dependence on temperature for NbCoSn, NbCoSn_{0.99}Sb_{0.01} and NbCoSn_{0.98}Sb_{0.02} before a heat treatment and FIG. 7B shows the coefficient dependence on temperature for the foregoing materials after the heat treatment, respectively;

FIG. 8 shows electric resistivity dependence on temperature, in which FIG. 8A shows the resistivity dependence on temperature for NbCoSn, NbCoSn_{0.99}Sb_{0.01}, and NbCoSn_{0.98}Sb_{0.02} before a heat treatment whereas FIG. 8B shows the resistivity dependence on temperature for the foregoing materials after the heat treatment, respectively; and

FIG. 9 shows power factor dependence on temperature for NbCoSn, NbCoSn_{0.99}Sb_{0.01}, and NbCoSn_{0.98}Sb_{0.02}.

### DETAILED DESCRIPTION OF THE INVENTION

As represented by the foregoing formula, a half-Heusler alloy according to the present invention can be made of only cation- or anion-forming atoms that become cations or anions respectively when an insufficient electron-occupying state is eliminated in s orbitals, p orbitals, and d orbitals. Thus, although a thermoelectric conversion material of the present invention does not meet the conventional guideline for combination (see JP 2001-189495 A) and uses a half-Heusler alloy, which has been considered as inferior in terms of performance, it exhibits good thermoelectric performance in a wide temperature range including the range of 250 K to 800 K.

The difference in electronegativity between the elements that consititutes a half-Heusler alloy is not large. For this reason, the state of electrons in a half-Heusler alloy is basically understood through covalent bonds of valence numbers. With very few exceptions, when a closed shell structure is attained in which the total of the valence number is 8 or 18, a band gap opens up in the vicinity of the Fermi level, realizing the properties of a semiconductor or of a semimetal in low temperatures. In addition, when it contains as a constituting element a transition metal or a metal having d electrons as the outermost shell electrons, a band in which d electrons, having good localization property, are hybridized with s electrons and p electrons, having good itinerant property, is formed in the conduction band and the valence band, unlike conventionally-known semiconductors. Due to this hybridized band, the density of states in the vicinity of the Fermi level, which serves for conduction, becomes larger than that of usual semiconductors, realizing a material having better electrical conduction and a larger Seebeck coefficient than conventional semiconductors.

In particular, a half-Heusler alloy represented by the formula QRL, where Q is at least one element selected from group 5 elements (V, Nb, and Ta), R is at least one element selected from Co, Rh, and Ir, and L is at least one element selected from Sn and Ge, shows an electricity transport phenomenon similar to that with semiconductors, and it has a narrow band gap; therefore, this half-Heusler alloy demonstrates good thermoelectric performance.

In half-Heusler alloys, substitution of the atoms is easily occured, and the substitution affects their physical properties sensitively. Accordingly, their physical properties can be controlled merely by substituting the atoms and changing the state in the vicinity of the Fermi level slightly. This can be used to increase the Seebeck coefficient and to reduce the electric resistivity. Specifically, in a half-Heusler alloy represented by the formula QRL, when part of the element L is substituted by an element Z (Z=Sb, In) and doped with a carrier, that is, when the foregoing formula is QR(L₁₋ₚZₚ), where 0<p<0.5, its electricity transport phenomenon can be controlled. With this control, the electric resistivity and thermal conductivity can be reduced, and it is thus possible to obtain a figure of merit higher than was conventionally obtained.

An appropriate amount of the element L to be substituted with the element Z is less than 50 atomic % (at %; 0<p<0.5), preferably 10 at % or less (0<p≦0.1), still more preferably 5 at % or less (0<p≦0.05), and particularly preferably 2 at % or less (0<p≦0.02), although it may depend on the combinations of the elements. When the amount of the dope exceeds 50 at %, the material becomes like a metal rather than like a semiconductor, and good thermoelectric performance cannot be obtained.

In order to obtain high thermoelectric performance, it is preferable that the element Q be niobium, the element R be cobalt, and the element L be tin. In the case where p is greater than 0, it is preferable that the element Z be antimony. Although combinations of the elements are not particularly limited, preferable combinations are: the combination in which Q is niobium, R is cobalt, L is tin, and p is 0, i.e., the combination represented by the formula NbCoSn; and the combination in which the Q is niobium, R is cobalt, L is tin, Z is antimony, and p is greater than 0, i.e., the combination represented by the formula NbCo (Sn₁₋ₚSbₚ) (0<p≦0.5). When 0<p≦0.02 in the latter composition, particularly high thermoelectric performance can be obtained.

There are some half-Heusler alloys that their thermoelectric performance can be improved by sintering. With the synergistic effect of sintering and doping, it is also possible to realize a thermoelectric conversion material having further higher performance.

In general, in terms of the peak value, the thermoelectric conversion material according to the present invention does not surpass Bi₂Te₃-based or PbTe-based materials, which are typical conventional thermoelectric conversion materials. However, the thermoelectric conversion material according to the present invention exhibits good characteristics in a wide temperature range, ranging from 250 K to 800 K; and moreover, within this temperature range, the performance becomes higher as the temperature increases. Accordingly, although there is no restriction on the temperature of use, the thermoelectric conversion material of the present invention is particularly suitable for the uses in a high temperature range such that, for example, part of the thermoelectric conversion material is heated to about 500 to 1200° C., such as co-generation.

The thermoelectric conversion material of the present invention is suitable for materials for consumer use because it can be made from the elements that are relatively inexpensive and readily available, such as niobium, cobalt, and tin.

The half-Heusler alloy according to the present invention may be made of either single crystal or polycrystal. Generally, that of single crystal exhibits good characteristics, whereas that of polycrystal is manufactured easily and is therefore suitable for mass production.

The half-Heusler alloy according to the present invention may be made of polyphase but preferably of single phase. When it is made of single phase, even higher thermoelectric conversion performance can be obtained.

The thermoelectric conversion material of the present invention may contain other components than the above-described half-Heusler alloy, for example, the elements other than the elements that constitute the half-Heusler alloy, but it is preferable that the above-described half-Heusler alloy be the main component, i.e., the component that accounts for 50 weight % or more.

The thermoelectric conversion material of the present invention can be manufactured by those methods that have adopted for preparing various half-Heusler alloys. Examples include an arc-melt method and a high-frequency melt method. A single crystal half-Heusler alloy can be obtained by melting the mixture of source materials and then growing a crystal while gradually cooling the melt.

Hereinbelow, embodiments of using the thermoelectric conversion material of the present invention are described with reference to the drawings.

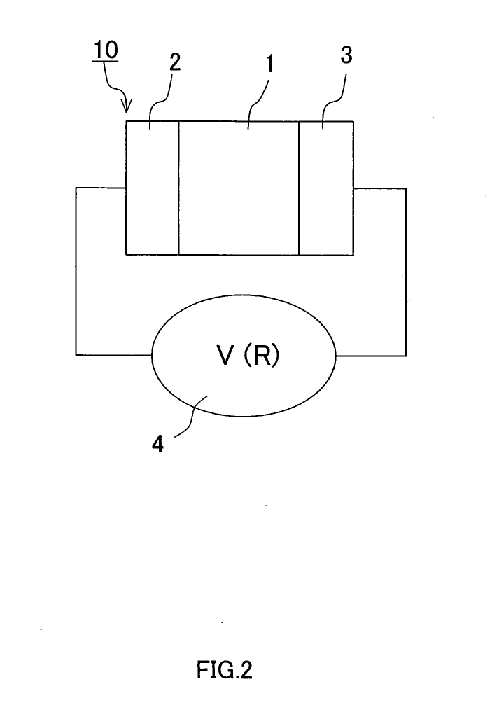

As shown in FIG. 2, the simplest configuration for using a thermoelectric conversion material 1 of the present invention as a thermoelectric conversion element 10 is that in which a first electrode 2 and a second electrode 3 are connected so as to sandwich the thermoelectric conversion material 1. When these electrodes 2 and 3 are connected to an external dc power supply (V) 4, the thermoelectric conversion element 10 can be used as a thermoelectric-conversion cooling element utilizing the Peltier effect. In this case, either one of the first electrode 2 or the second electrode 3 serves as a cooling part while the other serves as a heat-generating part. Thus, when the cooling part becomes lower in temperature than the surrounding, heat is transferred from outside (for example, an article or atmosphere that is in contact with the cooling part) to the cooling part.

When the first electrode 2 and the second electrode 3 are connected to the external load (R) 4, the thermoelectric conversion element 10 can be used as a thermoelectric-conversion power-generating element utilizing the Seebeck effect. In this case, when heat is supplied to either one of the electrode 2 or 3 to make it a high temperature part while the other is made a low temperature part, a dc current flows to the load 4. Thus, the thermoelectric conversion element 10 is used by incorporating it into a circuit including the power supply or load 4.

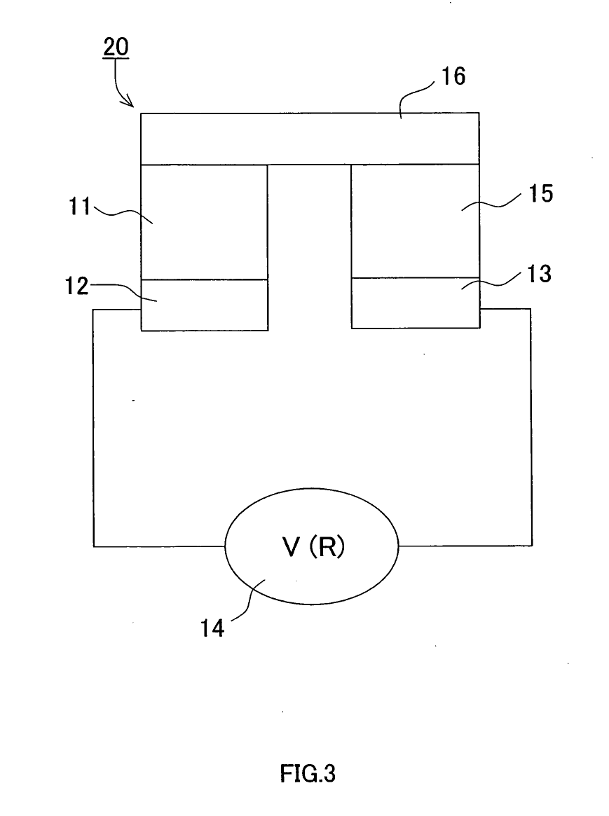

The carrier in the thermoelectric conversion material of the present invention is electrons, so it is an n-type thermoelectric conversion material having a negative Seebeck coefficient. For this reason, as shown in FIG. 3, when a thermoelectric conversion element 20 is configured using a p-type thermoelectric conversion material 15 together with the thermoelectric conversion material 11 according to the present invention, even higher thermoelectric performance is obtained. The thermoelectric conversion element 20 further includes an electrode 16 that is disposed between the n-type thermoelectric conversion material 11 and the p-type thermoelectric conversion material 15, and electrodes 12 and 13 that are disposed on opposing ends of the element 20, for connecting the element 20 to a power supply or load 14.

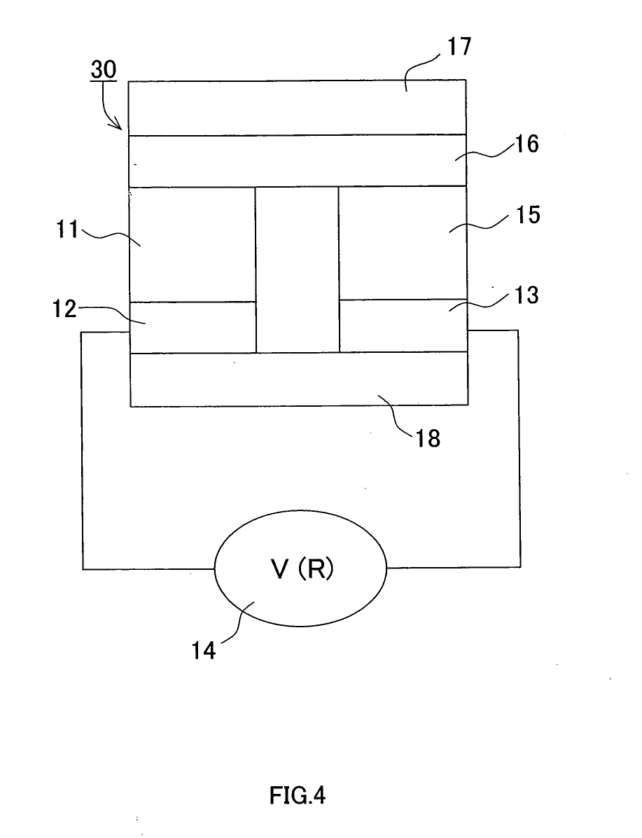

As shown in FIG. 4, it is also possible to configure a thermoelectric conversion element 30 that further includes insulators 17 and 18. In this element 30, the insulator 17 is connected to the electrode 16, and the insulator 18 is connected to the electrodes 12 and 13, respectively.

When a dc current is supplied from the power supply 14 to the thermoelectric conversion element 30 anticlockwise in the circuit of FIG. 4, the electrode 16 and the insulator 17 serve as a low temperature part whereas the electrodes 12, 13, and the insulator 18 serve as a high temperature part. Switching over the low temperature part and the high temperature part is effected by reversing the direction of the current. When the heat is appropriately released from the insulator 18, which is a high temperature part, the insulator 17, which is a low temperature part, becomes a heat-absorbing part (cooling part) that absorbs heat from outside (for example, an article or a fluid, such as gas and liquid, that is in contact with the insulator). In this case, the thermoelectric conversion element 30 is a local cooling element that converts electric energy into thermal energy. The device shown in FIG. 4 can be used as a cooling device that includes the thermoelectric conversion element 30 and the dc power supply 14 electrically connected to the element 30.

When, for example, the insulator 17 is exposed to a high temperature atmosphere or brought into contact with a high temperature fluid so that a temperature difference is caused between the insulators 17 and 18, an electromotive force is caused between the electrodes 12 and 13. This electromotive force can be taken out as electric power from the load 14. For supplying heat to the insulator 17, it is possible to utilize the exhaust heat from various devices or the body heat of living organisms such as human bodies. In that case, the thermoelectric conversion element 30 is a power-generating element that converts thermal energy supplied to the insulator 17 into electric energy. The device shown in FIG. 4 may be used as an electric apparatus including the thermoelectric conversion element 30 and the load 14 that operates with the current supplied from the element 30, which is electrically connected to the element 30. Suitable examples of the load 14 are electronic components represented by motors, lighting apparatus, and various resistance elements and the like, but it is not particularly limited thereto as long as it can perform a predetermined function with electric current. The foregoing term to “operate” means that the load performs a predetermined function.

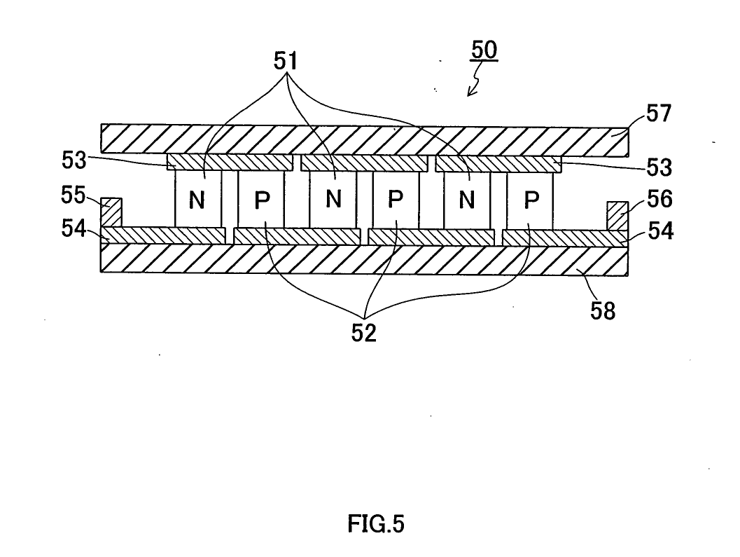

As shown in FIG. 5, a thermoelectric conversion element 50 may be configured such that n-type thermoelectric conversion materials 51 and p-type thermoelectric conversion materials 52 are connected alternately and electrically in series. This thermoelectric conversion element 50 is to be connected to an external power supply or an external load, via external electrodes (output electrodes) 55 and 56. Electrodes 53 and 54 are disposed at the contacts with the thermoelectric conversion materials 51 and 52. Along the current path in the element from one external electrode 55 (56) to the other external electrode 56 (55), the electrodes 53 (54) are present at passing points from the n-type materials 51 to the p-type materials 52, whereas the electrodes 54 (53) are present on passing points from the p-type materials 52 to the n-type materials 51. For example, when the element 50 is connected to a DC power supply, either one of the electrodes 53 or 54 becomes a heat-generating part and the other one becomes a heat-absorbing part. An insulator 57 and an insulator 58 are respectively in contact with the electrode 53 and the electrode 54. In other words, the electrodes 53 and 54 are alternately in contact with the same insulators 57 and 58. In this element 50, for example, the insulator 57 functions as a heat-releasing part whereas the insulator 58 functions as a heat-absorbing part (cooling part), respectively.

Although there are no particular restrictions on the p-type thermoelectric conversion materials, usable examples include materials formed of (Bi, Sb)₂Te₃ alloys, Bi—Sb alloys, Pb—Te alloys, Ce—Fe—Sb type or Co—Sb type skutterudite compounds, and a pseudobinary solid solution of GaTe and AgSbTe₂, known as TAGS.

In order to reduce environmental load, it is preferable to use as the p-type thermoelectric conversion materials, for example, Si—Ge alloys, Fe—Si alloys, Mg—Si alloys, or AMO (A is an alkali metal or alkaline-earth metal, and M is a transition metal) type layered oxides.

As the material for the electrodes, various metallic materials, such as copper, may be used. The material for the insulators is not particularly limited either, and it may be selected from ceramic substrates, oxide insulators, and the like, as appropriate for the use.

### EXAMPLE

Half-Heusler alloys having the compositions of NbCoSn and NbCo(Sn₁₋ₚSbₚ) (p=0.01 or 0.02) were prepared, and their characteristics were measured.

Fabrication Method

As the source materials for Nb, Co, and Sn, powders of respective simple substances having a purity of 99.9% were prepared, and as the source material for Sb, powder of the simple substance having a purity of 99.7% was prepared.

These materials were weighed to be in the stoichiometric proportions based on the above-noted compositions, then mixed until the mixture becomes uniform, and formed into a pellet form. The pellets were placed on water-cooled copper (hearth) and the pressure was reduced to 2.0×10⁻³ Pa. Thereafter, an Ar gas was introduced, and the pellets were arc-melted in an Ar gas atmosphere at 300 mmHg (about 0.04 MPa). At this time, the arc voltage was 18 to 20 V, and the arc current was 120 to 130 A. The alloy materials obtained by the arc melting were repeatedly remelted a necessary number of times so that the composition becomes uniform.

Two samples were prepared for each of the three kinds of samples, NbCoSn and NbCo(Sn₁₋ₚSbₚ) (p=0.01 or 0.02). Among them, one from each was sintered with a heat treatment at 850° C. for 6 days in a reduced pressure of 2.0×10⁻³ Pa.

### Evaluation Method and the Results

Crystal Structure

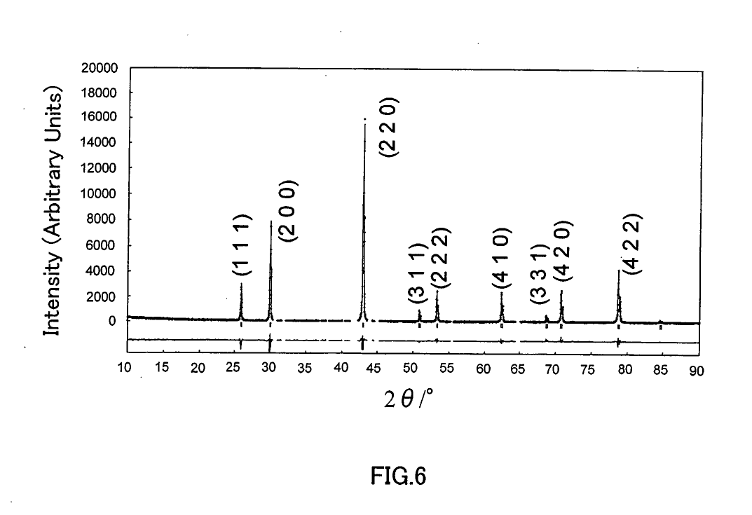

X-ray diffraction was used to determine whether a desired substance was obtained. An example of the results is shown in FIG. 6. In all the X-ray diffraction charts, sufficiently sharp peaks were observed, and it was confirmed that all the samples had the crystal structure of half-Heusler alloy and were in single phase.

Seebeck Coefficient

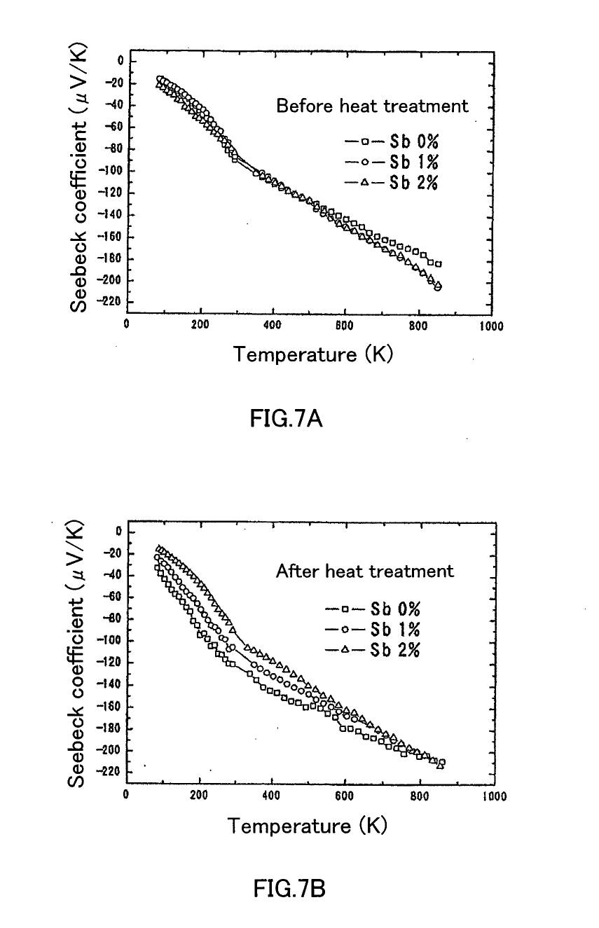

Seebeck coefficients were measured in a temperature range from the liquid nitrogen temperature (77 K) to 873 K by a temperature difference-thermal electromotive force method. The results are shown in FIGS. 7A and 7B, and Table 1. FIGS. 7A and 7B are graphs plotted based on Table 1.

As seen from FIGS. 7A and 7B, Seebeck coefficients of about −90 μV/K were obtained at room temperature for all the samples, and the absolute values of the Seebeck coefficients increased as the temperature increased up to a temperature range exceeding 800 K. The Sb doping did not have a great influence on the absolute values of the Seebeck coefficients for the samples before the heat treatment. Although applying the heat treatment increased the absolute values of the Seebeck coefficients, the Sb doping caused the absolute values of the Seebeck coefficients to decrease after the heat treatment.

TABLE 1
Seebeck coefficient (μV/K)

| | 200 K | 400 K | 600 K | 800 K |
|---|---|---|---|---|
| Before heat treatment | | | | |
| Sb 0% | −47.825 | −110.73 | −142.32 | −174.18 |
| Sb 1% | −43.412 | −107.98 | −148.73 | −191 |
| Sb 2% | −53.917 | −109.87 | −150.34 | −188.33 |
| After heat treatment | | | | |
| Sb 0% | −94.091 | −144.45 | −178.21 | −203.76 |
| Sb 1% | −70.752 | −131.27 | −166.99 | −199.61 |
| Sb 2% | −47.956 | −117.96 | −161.84 | −199.97 |

Electric Resistivity

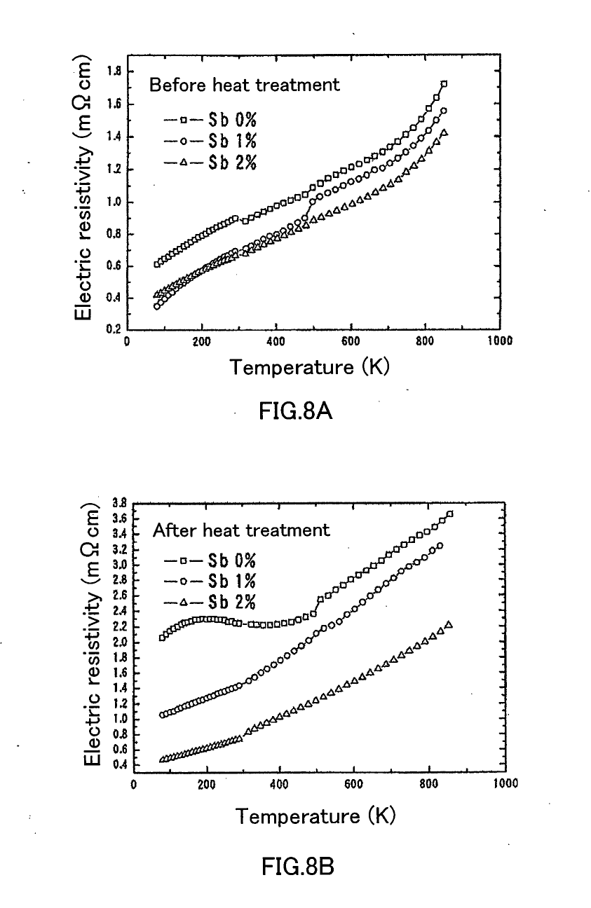

Electric resistivities measured by a dc four-terminal resistance measurement are shown in FIGS. 8A and 8B, and Table 2. FIGS. 8A and 8B are graphs plotted based on Table 2.

As seen from FIG. 8A, all the samples showed electric resistivities of 0.8 mΩcm or less at room temperature before the heat treatment, which were considerably lower than an electric resistivity that is normally expected from the high Seebeck coefficient of −90 μV/K. This proves that the thermoelectric performance of this substance is outstanding. In addition, it was confirmed that the electric resistivities decreased due to the Sb doping. This suggests that, by the Sb doping, a carrier was implanted into the samples that show semiconductor-like behaviors. The fact that the Sb doping reduced the electric resistivities while marinating the Seebeck coefficients indicates that the thermoelectric performance was further improved by the carrier doping.

As shown in FIG. 8B, the electric resistivities showed a tendency to increase due to the heat treatment, but the decreases in the electric resistivities due to the Sb doping became more conspicuous than those observed before the heat treatment. For example, when Sb is added at 2%, the electric resistance almost halved. This suggests that the thermoelectric performance can be further improved by controlling the heat treatment and the amount of the dope.

TABLE 2
Electric Resistivity (mΩcm)

| | 200 K | 400 K | 600 K | 800 K |
|---|---|---|---|---|
| Before heat treatment | | | | |
| Sb 0% | 0.79322 | 0.97831 | 1.2139 | 1.5059 |
| Sb 1% | 0.57382 | 0.79904 | 1.1247 | 1.3889 |
| Sb 2% | 0.57175 | 0.77339 | 0.98769 | 1.2616 |
| After heat treatment | | | | |
| Sb 0% | 2.2955 | 2.2258 | 2.8072 | 3.4237 |
| Sb 1% | 1.2723 | 1.7635 | 2.4245 | 3.0948 |
| Sb 2% | 0.61829 | 1.0246 | 1.4897 | 2.0012 |

Power Factor

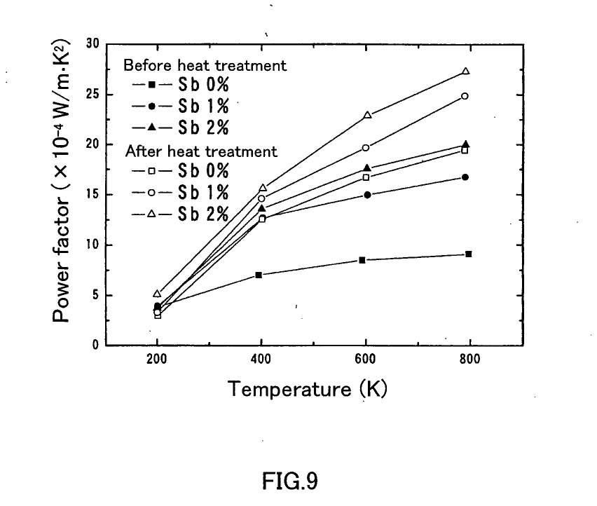

Power factor values P (P=S²/ρ) are shown in FIG. 9 and Table 3. FIG. 9 is a graph plotted based on Table 3.

As seen from FIG. 9, power factor values P monotonously increased as the temperature increased. The maximum values were high, about 11×10⁻⁴ W/m·K² at room temperature and about 28×10⁻⁴ W/m·K² at a high temperature (800 K) (both values were for the samples doped with Sb at 2% that are before heat treatment). Since the Sb doping made it possible to reduce electric resistivities without greatly varying Seebeck coefficients, power factor values P became greater. Although a heat treatment increases both the absolute values of Seebeck coefficients and the electric resistivities, it is possible to obtain a high power factor if the heat treatment is combined with carrier doping.

TABLE 3
Power Factor (×10⁻⁴ W/m · K²)

| | 200 K | 400 K | 600 K | 800 K |
|---|---|---|---|---|
| Before heat treatment | | | | |
| Sb 0% | 2.98 | 12.53 | 16.68 | 19.43 |
| Sb 1% | 3.28 | 14.59 | 19.67 | 24.87 |
| Sb 2% | 5.08 | 15.61 | 22.88 | 27.29 |
| After heat treatment | | | | |
| Sb 0% | 3.86 | 7.03 | 8.49 | 9.1 |
| Sb 1% | 3.93 | 12.7 | 14.95 | 16.74 |
| Sb 2% | 3.72 | 13.58 | 17.58 | 19.98 |

As has been described above, the present invention can provide a thermoelectric conversion material that exhibits high thermoelectric performance in a wide temperature range at least ranging from 250 to 800 K. The thermoelectric conversion material can be made from the elements that are relatively inexpensive and readily available, such as niobium, cobalt, and tin. With these characteristics, the thermoelectric conversion material of the present invention is useful in applications to various apparatus for consumer uses. The thermoelectric conversion material of the present invention also has high utility value in uses at high temperatures such as co-generation since it shows high thermoelectric performance in a high temperature range.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A thermoelectric conversion material comprising a half-Heusler alloy represented by the formula QR(L₁₋ₚZₚ), where Q is at least one element selected from group 5 elements, R is at least one element selected from cobalt, rhodium, and iridium, L is at least one element selected from tin and germanium, Z is at least one element selected from indium and antimony, and p is a numerical value that is equal to or greater than 0 and less than 0.5.

2. The thermoelectric conversion material according to claim 1, wherein p is greater than 0 and less than 0.5.

3. The thermoelectric conversion material according to claim 2, wherein p is greater than 0 and equal to or less than 0.05.

4. The thermoelectric conversion material according to claim 3, wherein p is greater than 0 and equal to or less than 0.02.

5. The thermoelectric conversion material according to claim 1, wherein Q is niobium.

6. The thermoelectric conversion material according to claim 1, wherein R is cobalt.

7. The thermoelectric conversion material according to claim 1, wherein L is tin.

8. The thermoelectric conversion material according to claim 1, wherein p is greater than 0 and Z is antimony.

9. The thermoelectric conversion material according to claim 1, wherein Q is niobium, R is cobalt, L is tin, and p is 0.

10. The thermoelectric conversion material according to claim 1, wherein p is greater than 0, Q is niobium, R is cobalt, L is tin, and Z is antimony.

11. The thermoelectric conversion material according to claim 1, wherein the half-Heusler alloy is made of single phase.

12. A thermoelectric conversion element comprising a thermoelectric conversion material according to claim 1, and a first electrode and a second electrode connected to the thermoelectric conversion material.

13. The thermoelectric conversion element according to claim 12, further comprising a p-type thermoelectric conversion material connected to at least one of the first electrode and the second electrode.

14. The thermoelectric conversion element according to claim 12, further comprising an insulator connected to at least one of the first electrode and the second electrode.

15. A thermoelectric conversion element comprising:
n-type thermoelectric conversion materials and p-type thermoelectric conversion materials, wherein:
the n-type thermoelectric conversion materials and the p-type thermoelectric conversion materials are alternately and electrically connected in series, and
at least one of the n-type thermoelectric conversion materials is a thermoelectric conversion material according to claim 1.

16. A cooling device comprising a thermoelectric conversion element according to claim 12 and a DC power supply electrically connected to the thermoelectric conversion element.

17. An electric apparatus comprising:
a thermoelectric conversion element according to claim 12; and
a load electrically connected to the thermoelectric conversion element and operated by a current supplied from the thermoelectric conversion element.

18. An electric power generating method of using a thermoelectric conversion element comprising a thermoelectric conversion material and a first electrode and a second electrode connected to the thermoelectric conversion material, the method comprising:
supplying heat so that a temperature difference is caused between the first electrode and the second electrode so as to produce a potential difference between the first electrode and the second electrode, wherein
the thermoelectric conversion material comprises a half-Heusler alloy represented by the formula QR(L₁₋ₚZₚ), where Q is at least one element selected from group 5 elements, R is at least one element selected from cobalt, rhodium, and iridium, L is at least one element selected from tin and germanium, Z is at least one element selected from indium and antimony, and p is a numerical value that is equal to or greater than 0 and less than 0.5.

19. The method of generating electric power according to claim 18, wherein p is greater than 0 and less than 0.5.

20. The method of generating electric power according to claim 19, wherein p is greater than 0 and equal to or less than 0.05.

21. The method of generating electric power according to claim 20, wherein p is greater than 0 and equal to or less than 0.02.

22. The method of generating electric power according to claim 18, wherein Q is niobium.

23. The method of generating electric power according to claim 18, wherein R is cobalt.

24. The method of generating electric power according to claim 18, wherein L is tin.

25. The method of generating electric power according to claim 18, wherein p is greater than 0 and Z is antimony.

26. The method of generating electric power according to claim 18, wherein Q is niobium, R is cobalt, L is tin, and p is 0.

27. The method of generating electric power according to claim 18, wherein p is greater than 0, Q is niobium, R is cobalt, L is tin, and Z is antimony.

28. The method of generating electric power according to claim 18, wherein the half-Heusler alloy is made of single phase.

29. The method of generating electric power according to claim 18, wherein the thermoelectric conversion element further comprises a p-type thermoelectric conversion material connected to at least one of the first electrode and the second electrode.

30. The method of generating electric power according to claim 18, wherein the thermoelectric conversion element further comprises an insulator connected to at least one of the first electrode and the second electrode.

31. A cooling method of using a thermoelectric conversion element comprising a thermoelectric conversion material and a first electrode and a second electrode connected to the thermoelectric conversion material, the method comprising:
causing a potential difference between the first electrode and the second electrode so as to produce a temperature difference between the first electrode and the second electrode such that one of the first electrode and the second electrode is made a low temperature part, wherein
the thermoelectric conversion material comprises a half-Heusler alloy represented by the formula QR(L₁₋ₚZₚ), where Q is at least one element selected from group 5 elements, R is at least one element selected from cobalt, rhodium, and iridium, L is at least one element selected from tin and germanium, Z is at least one element selected from indium and antimony, and p is a numerical value that is equal to or greater than 0 and less than 0.5.

32. The cooling method according to claim 31, wherein p is greater than 0 and less than 0.5.

33. The cooling method according to claim 32, wherein p is greater than 0 and equal to or less than 0.05.

34. The cooling method according to claim 33, wherein p is greater than 0 and equal to or less than 0.02.

35. The cooling method according to claim 31, wherein Q is niobium.

36. The cooling method according to claim 31, wherein R is cobalt.

37. The cooling method according to claim 31, wherein L is tin.

38. The cooling method according to claim 31, wherein p is greater than 0 and Z is antimony.

39. The cooling method according to claim 31, wherein Q is niobium, R is cobalt, L is tin, and p is 0.

40. The cooling method according to claim 31, wherein p is greater than 0, Q is niobium, R is cobalt, L is tin, and Z is antimony.

41. The cooling method according to claim 31, wherein the half-Heusler alloy is made of single phase.

42. The cooling method according to claim 31, wherein the thermoelectric conversion element further comprises a p-type thermoelectric conversion material connected to at least one of the first electrode and the second electrode.

43. The cooling method according to claim 31, wherein the thermoelectric conversion element further comprises an insulator connected to at least one of the first electrode and the second electrode.
